(19) United States
(12) Patent Application Publication
(10) Pub. No.: US 2011/0277810 A1
(43) Pub. Date: Nov. 17, 2011

(54) PHOTOVOLTAIC ASSEMBLY WITH HEATING CURTAINS

(75) Inventor: Ching-Yee Chak, Hong Kong (HK)

(73) Assignee: Du Pont Apollo Limited, Hong Kong (HK)

(21) Appl. No.: 13/101,153

(22) Filed: May 5, 2011

Related U.S. Application Data
(60) Provisional application No. 61/334,098, filed on May 12, 2010.

(51) Int. Cl. H01L 31/042

(52) U.S. Cl. 136/244

(57) ABSTRACT

A photovoltaic assembly includes a photovoltaic panel, two curtains and two rollers. The photovoltaic panel is for converting light into electricity and comprising two opposite surfaces. Two curtains are for absorbing solar heat to roast the photovoltaic panel when the two curtains are disposed to cover the two opposite surfaces of the photovoltaic panel. Each of the two curtains includes a stack of a reflective layer, a high thermal capacity layer and a transparent layer. The high thermal capacity layer is sandwiched between the reflective layer and the transparent layer. The reflective layer is closer to the photovoltaic panel than the high thermal capacity layer and the transparent layer are when the two curtains cover the two opposite surfaces of the photovoltaic panel. Each roller includes a rotatable shaft for rolling each of the two curtains.

### RELATED APPLICATIONS

This application claims priority to U.S. Provisional Application Ser. No. 61/334,098, filed May 12, 2010, which is herein incorporated by reference.

### BACKGROUND

1. Field of Invention

The present invention relates to a photovoltaic panel. More particularly, the present invention relates to a photovoltaic panel made from amorphous hydrogenated silicon.

2. Description of Related Art

Electronic devices, including energy sensitive solar cells, are vulnerable to various types of degradation. One important kind of degradation of a-Si:H (amorphous hydrogenated silicon) made solar panel arises from the creation of dangling bonds so that the performance is degraded in converting light to electricity.

It is known in some scientific papers that the dangling bonds within the degraded solar panel can be diminished and to be repaired if the externally applied energy sources are existed. In particular, the degraded solar panel can be roasted in an oven for a predetermined period of time to recover its performance in converting light to electricity to some degree.

However, after a solar panel is installed on a roof, it is costly and inconvenient to take the degraded solar panel apart from the roof and then roast it in an oven so as to recover its performance. Thus, there is no practical and convenient solution in the conventional art to recover the degraded solar panel's performance in converting light to electricity.

### SUMMARY

It is therefore an objective of the present invention to provide a practical and convenient solution to deal with the problems in the conventional art to recover the degraded solar panel's performance in converting light to electricity.

In accordance with the foregoing and other objectives of the present invention, a photovoltaic assembly includes a photovoltaic panel, two curtains and two rollers. The photovoltaic panel is for converting light into electricity and comprising two opposite surfaces. Two curtains are for absorbing solar heat to roast the photovoltaic panel when the two curtains are disposed to cover the two opposite surfaces of the photovoltaic panel. Each of the two curtains includes a stack of a reflective layer, a high thermal capacity layer and a transparent layer. The high thermal capacity layer is sandwiched between the reflective layer and the transparent layer. The reflective layer is closer to the photovoltaic panel than the high thermal capacity layer and the transparent layer are when the two curtains cover the two opposite surfaces of the photovoltaic panel. Each roller includes a rotatable shaft for rolling each of the two curtains.

According to an embodiment disclosed herein, the photovoltaic assembly further includes a motor connected to the rotatable shaft for rolling each of the two curtains.

According to another embodiment disclosed herein, the roller includes a hollow cylinder-shaped housing to accommodate a rolled each of the two curtains.

According to another embodiment disclosed herein, each of the two curtains has substantially the same area as either one of the two opposite surfaces of the photovoltaic panel.

According to another embodiment disclosed herein, each of the two curtains is larger in area than either one of the two opposite surfaces of the photovoltaic panel.

According to another embodiment disclosed herein, the two rollers are respectively disposed at two opposite edges of the photovoltaic panel.

According to another embodiment disclosed herein, each of the two curtains comprises an insulation and moisture resistance material disposed at all edges of the stack of the reflective layer, the high thermal capacity layer and the transparent layer.

According to another embodiment disclosed herein, the photovoltaic panel comprises an insulation and moisture resistance material disposed at all edges thereof.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a perspective view of a photovoltaic assembly according to an embodiment disclosed herein;

FIG. 2 illustrates another perspective view of a photovoltaic assembly according to an embodiment disclosed herein; and

FIG. 3 illustrates a cross-sectional view of a roller taken along 3-3′ in FIG. 2.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

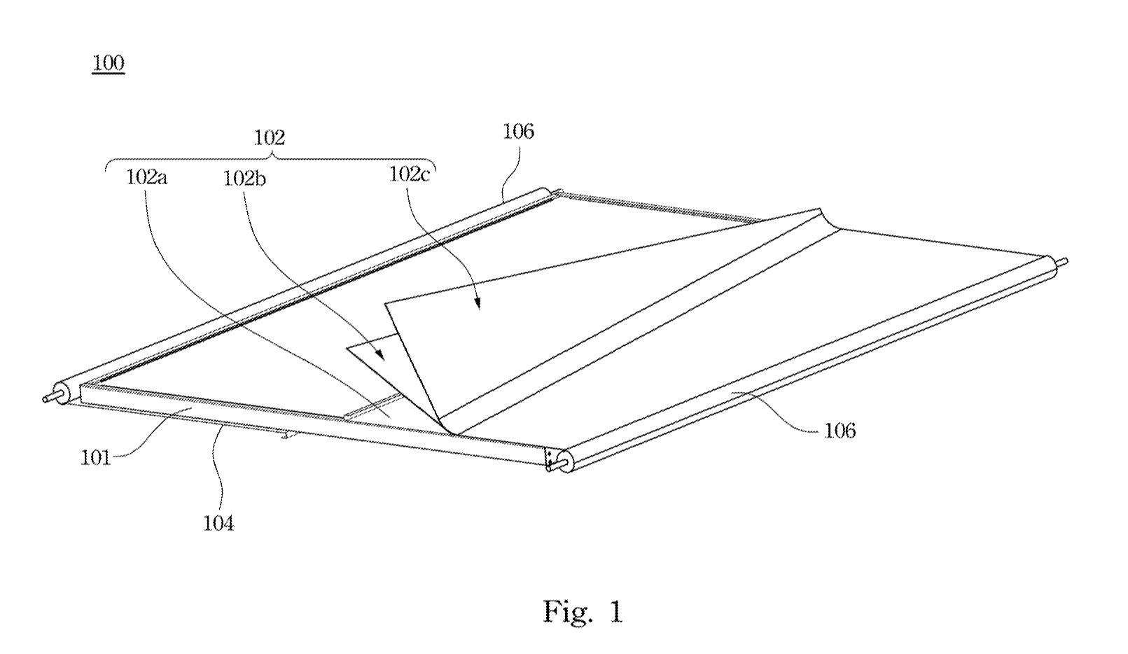

FIG. 1 illustrates a perspective view of a photovoltaic assembly 100 according to an embodiment disclosed herein. The photovoltaic assembly 100 includes a photovoltaic panel 101, two curtains (102, 104) and two rollers 106. The photovoltaic panel 101 contains a plurality of photovoltaic cells, which are made from amorphous hydrogenated silicon (a-Si:H), for converting light into electricity. After the photovoltaic cells have operated for a period of time, two curtains (102, 104) are used to maintain the photovoltaic panel 101 to improve its performance in converting light to electricity. In particular, the two curtains (102, 104) are pulled out of the rollers 106 to fully cover two opposite surfaces of the photovoltaic panel 101, i.e. an upper surface and a lower surface, for roasting the photovoltaic panel 101 by solar heat. In this maintenance status, the photovoltaic panel 101 does not output power or electricity, e.g. an inner terminal is electrically disconnected with an external terminal. The two curtains (102, 104) are to absorb solar heat to roast the photovoltaic panel 101 up to a predetermined temperature, e.g. at least about 70° C., so as to recover its performance in converting light to electricity in some degree.

Each of the two curtains (102, 104) at least includes a stack of three layers: a reflective layer 102a, a high thermal capacity layer 102b and a transparent layer 102c. The reflective layer 102a is closer to the photovoltaic panel 101 than the high thermal capacity layer 102b and the transparent layer 102c are when the two curtains (102, 104) cover the two opposite surfaces of the photovoltaic panel 101. The high thermal capacity layer 102b is sandwiched between the reflective layer 102a and the transparent layer 102c.

The arrangement for the stack of three layers is to obtain the solar heat as much as possible such that the photovoltaic panel 101 can be roasted by enough solar heat. In particular, the high thermal capacity layer 102b is made from darker materials, e.g. black materials, so as to absorb solar heat efficiently. The transparent layer 102c is to protect the high thermal capacity layer 102b and permits solar light to be passed through and absorbed by the high thermal capacity layer 102b. The reflective layer 102a is to redirect solar light back to and to be absorbed by the high thermal capacity layer 102b.

The two rollers 106 are installed at two opposite edges of the photovoltaic panel 101 to store the two curtains (102, 104) within thereof when the two curtains (102, 104) are withdrawn from the two opposite surfaces of the photovoltaic panel 101.

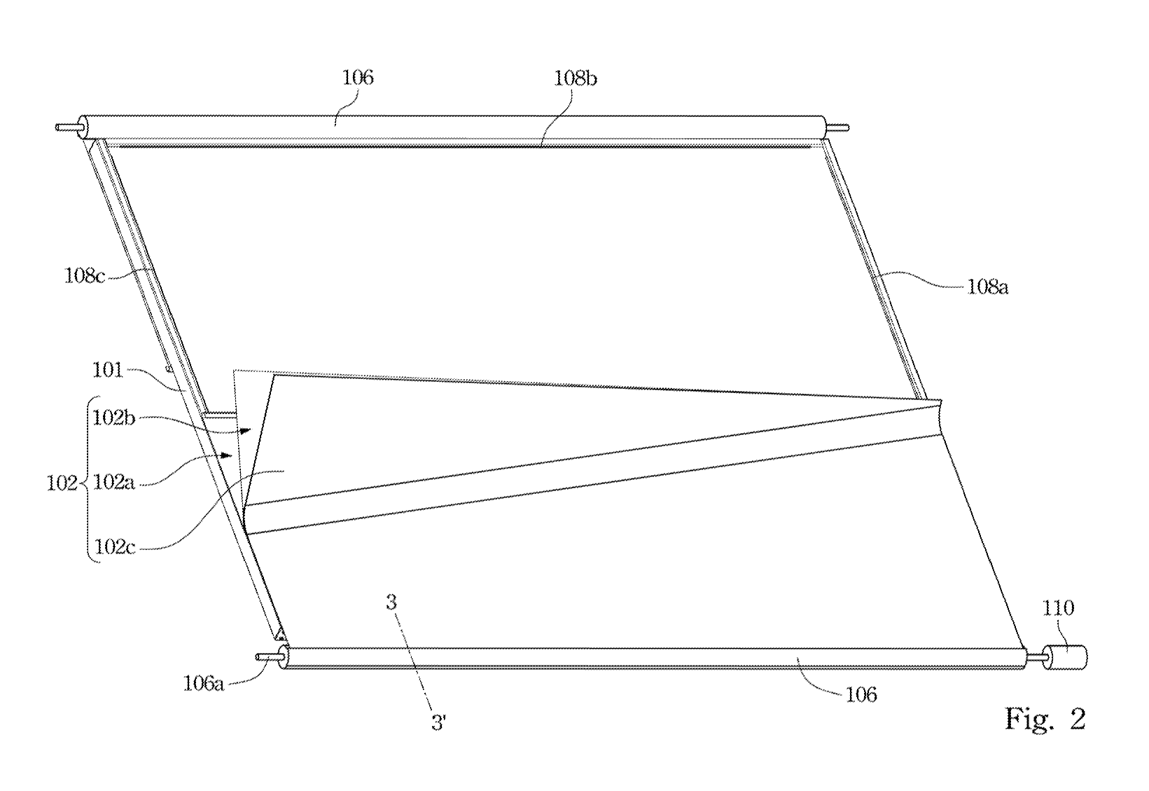

FIG. 2 illustrates another perspective view of a photovoltaic assembly according to an embodiment disclosed herein. In order to roast the photovoltaic assembly 100 up to a higher temperature, insulation and moisture resistance materials (108a, 108b, 108c) are installed at all edges of the photovoltaic assembly 100 to reserve solar heat. The same materials, e.g. 108a, 108b, 108c, can also be installed at all edges of the stack of the reflective layer 102a, the high thermal capacity layer 102b and the transparent layer 102c for the same purpose. Besides, in order to fully cover the two opposite surfaces of the photovoltaic panel 101, each of the two curtains (102, 104) has substantially the same area as either one of the two opposite surfaces of the photovoltaic panel 101, or each of the two curtains (102, 104) is larger in area than either one of the two opposite surfaces of the photovoltaic panel 101. Each of the two rollers 106 has a rotatable shaft 106a connected with and driven by a motor 110 so as to roll a curtain thereon.

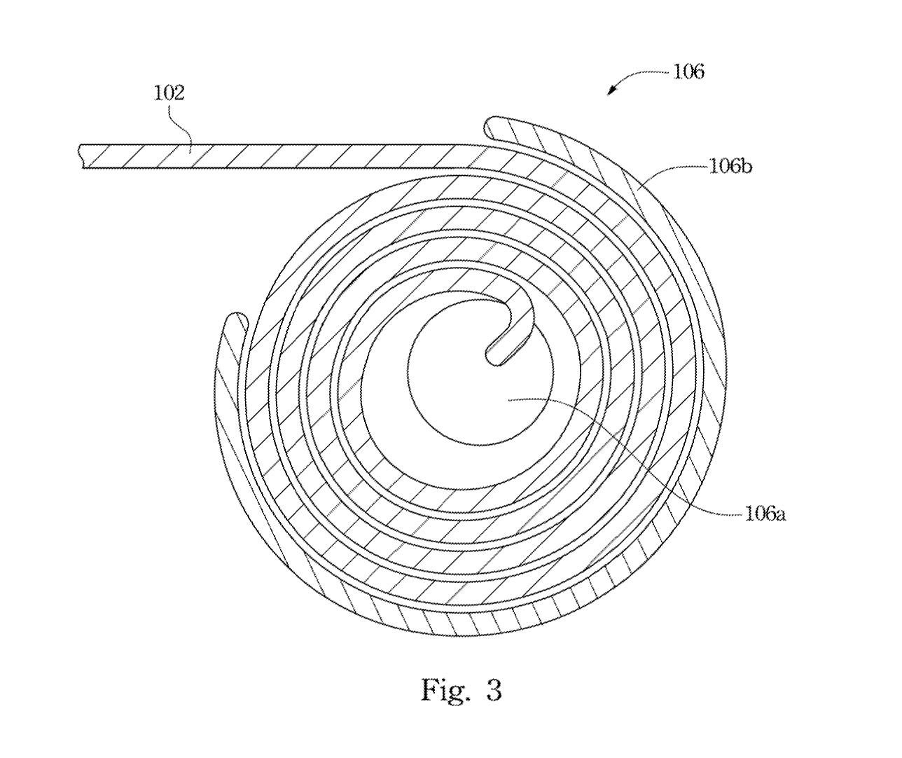

FIG. 3 illustrates a cross-sectional view of a roller taken along 3-3′ in FIG. 2. Each roller 106 basically includes a rotatable shaft 106a and a hollow cylinder-shaped housing 106b. When the curtain 102 is not needed, i.e. the photovoltaic panel begins to convert light to electricity, the rotatable shaft 106a, driven by the motor 110 (as illustrated in FIG. 2), roll the curtain 102 back within the hollow cylinder-shaped housing 106b so that the housing 106b can protect the curtain 102 from the external environment, including temperature, humidity, and impacts. When the curtain 102 is needed, users may manually pull or use a mechanism (powered by electricity) to pull the curtain 102 out of the housing 106b.

An experiment has been executed for the a-Si:H made solar panel, the result is listed in Table 1 below. The “Initial” status denotes all measured parameters when the a-Si:H made solar panel is performed under a testing light soaking system with an irradiation of 1000 W/m². The “After 60 kWhr of solar radiation” status denotes all measured parameters when the a-Si:H made solar panel receives 1000 W solar radiation for 60 hrs. It is noted that the maximum output power of the solar panel is degraded from 125.22 W to 109.18 W after 60 kWhr of solar radiation. A recovery process is then performed, i.e. roasting the solar panel at 135° C. for 45 minutes, to repair its performance in converting light to electricity. It is noted that the maximum output power of the solar panel is recovered from 109.18 W up to 119.92 W. That is, after a photovoltaic panel has been roasted for a desired period, its performance in converting light to electricity can be recovered in some degree. Therefore, an operation life of the a-Si:H made photovoltaic panel can be prolonged.

TABLE 1

| | | | After roasting |
|---|---|---|---|
| | | After 60 kWhr of | at 135° C. |
| | Initial | solar radiation | for 45 minutes |
| Short circuit current (A) | 1.7 | 1.68 | 1.7 |
| Open circuit voltage (V) | 103.67 | 100.16 | 101.81 |
| Maximum output power | 125.22 | 109.18 | 119.92 |
| point (W) | | | |
| Series resistance (Ω) | 6.75 | 6.29 | 6.88 |
| Shunt resistance (Ω) | 805.512 | 711.93 | 734.58 |

According to the above-discussed embodiments, the photovoltaic assembly is equipped with heating curtains to roast its photovoltaic panel when degradation occurs in its performance of converting light to electricity. The heating curtain in situ, instead of an oven in a remote place, provides a practical and convenient solution to recover the photovoltaic panel's performance in converting light to electricity.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic assembly comprising:
a photovoltaic panel for converting light into electricity and comprising two opposite surfaces;
two curtains for absorbing solar heat to roast the photovoltaic panel when the two curtains are disposed to cover the two opposite surfaces of the photovoltaic panel, each of the two curtains comprising a stack of a reflective layer, a high thermal capacity layer and a transparent layer, wherein the high thermal capacity layer is sandwiched between the reflective layer and the transparent layer, the reflective layer being closer to the photovoltaic panel than the high thermal capacity layer and the transparent layer are when the two curtains cover the two opposite surfaces of the photovoltaic panel; and
two rollers each comprising a rotatable shaft for rolling each of the two curtains.

2. The photovoltaic assembly of claim 1, wherein the high thermal capacity layer comprises a black material.

3. The photovoltaic assembly of claim 1, further comprising a motor connected to the rotatable shaft for rolling each of the two curtains.

4. The photovoltaic assembly of claim 1, wherein the roller comprises a hollow cylinder-shaped housing to accommodate a rolled each of the two curtains.

5. The photovoltaic assembly of claim 1, wherein each of the two curtains has substantially the same area as either one of the two opposite surfaces of the photovoltaic panel.

6. The photovoltaic assembly of claim 1, wherein each of the two curtains is larger in area than either one of the two opposite surfaces of the photovoltaic panel.

7. The photovoltaic assembly of claim 1, wherein the two rollers are respectively disposed at two opposite edges of the photovoltaic panel.

8. The photovoltaic assembly of claim 1, wherein each of the two curtains comprises an insulation and moisture resistance material disposed at all edges of the stack of the reflective layer, the high thermal capacity layer and the transparent layer.

9. The photovoltaic assembly of claim 1, wherein the photovoltaic panel comprises an insulation and moisture resistance material disposed at all edges thereof.
